(19) United States
(12) Patent Application Publication
(10) Pub. No.: US 2020/0189239 A1
(43) Pub. Date: Jun. 18, 2020

(54) COVER WINDOW STRUCTURE AND FLEXIBLE DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventors: Xia CHEN, Wuhan, Hubei (CN); Chen ZHAO, Wuhan, Hubei (CN)

(21) Appl. No.: 16/337,060

(22) PCT Filed: Mar. 13, 2019
(86) PCT No.: PCT/CN2019/078027

§ 371 Date: Mar. 27, 2019

(30) Foreign Application Priority Data
Dec. 17, 2018 (CN) 201811542954.X

(51) Int. Cl. B32B 17/10; H01L 51/52; B32B 7/12; B32B 3/30

(52) U.S. Cl. CPC B32B 17/1055; H01L 51/5237; B32B 7/12; B32B 2307/412; H01L 2251/5338; B32B 2457/206; B32B 3/30

(57) ABSTRACT

A cover window structure and a flexible display device are provided. The cover window structure includes a flexible cover window layer and a glass layer. The flexible cover window layer is disposed on the glass layer. Hardness and bendability of the cover window structure can be effectively enhanced by the flexible cover window layer and the glass layer.

### FIELD OF INVENTION

The present disclosure relates to the field of display technologies, and more particularly to a cover window structure and a flexible display device.

### BACKGROUND OF INVENTION

Organic light emitting diode (OLED) display devices include a display panel and a cover window structure. The cover window structure is disposed on a front side (that is, a display side) of the display panel to protect the display panel.

However, in a prior art, the cover window structure is made of a flexible material, such that a hardness thereof is small and the display panel cannot be effectively protected. In another prior art, the cover window structure adopts a material having a relatively high hardness, and thus is easily broken during a bending process, and cannot effectively protect the display panel, thereby affecting a performance of the OLED display devices.

Therefore, there is a need to provide a cover window structure and a flexible display device to solve issues of the prior art.

### SUMMARY OF INVENTION

To solve the above technical problem, the present disclosure provides a cover window structure including a flexible cover window layer and a glass layer. The flexible cover window layer is disposed on the glass layer.

In an embodiment of the present disclosure, the cover window structure further includes a first optical adhesive layer, the flexible cover window layer, the first optical adhesive layer, and the glass layer are sequentially disposed such that the cover window structure includes a multilayer composite structure.

In an embodiment of the present disclosure, the flexible cover window layer is a plastic cover window layer.

In an embodiment of the present disclosure, the first optical adhesive layer is an optically clear adhesive layer, and a thickness of the first optical adhesive layer is less than or equal to 20 um.

In an embodiment of the present disclosure, the cover window structure further includes a second optical adhesive layer and an ink layer, the ink layer is disposed at an end of the glass layer and positioned at one side of the glass layer away from the first optical adhesive layer, and the second optical adhesive layer is disposed around the ink layer.

In an embodiment of the present disclosure, a thickness of the glass layer ranges between 30 um and 70 um.

In an embodiment of the present disclosure, the flexible cover window layer includes an organic polymer film and a hard coating layer, and the hard coating layer is disposed on the organic polymer film.

In an embodiment of the present disclosure, a thickness of the organic polymer film has ranges between 30 um and 50 um.

In an embodiment of the present disclosure, the organic polymer film is a colorless transparent polyimide film, and a thickness of the hard coating layer ranges between 10 um and 30 um.

In an embodiment of the present disclosure, the hard coating layer includes a plurality of grooves or a plurality of protrusion structures, and the grooves or the protrusion structures of the hard coating layer contact the glass layer.

The present disclosure further provides a flexible display device including a display panel and a cover window structure disposed on the display panel. The cover window structure includes a flexible cover window layer and a glass layer. The flexible cover window layer is disposed on the glass layer.

In an embodiment of the present disclosure, the cover window structure further includes a first optical adhesive layer, the flexible cover window layer, the first optical adhesive layer, and the glass layer are sequentially disposed such that the cover window structure includes a multilayer composite structure.

In an embodiment of the present disclosure, the flexible cover window layer is a plastic cover window layer.

In an embodiment of the present disclosure, the first optical adhesive layer is an optically clear adhesive layer, and a thickness of the first optical adhesive layer is less than or equal to 20 um.

In an embodiment of the present disclosure, the cover window structure further includes a second optical adhesive layer and an ink layer, the ink layer is disposed at an end of the glass layer and positioned at one side of the glass layer away from the first optical adhesive layer, and the second optical adhesive layer is disposed around the ink layer.

In an embodiment of the present disclosure, a thickness of the glass layer ranges between 30 um and 70 um.

In an embodiment of the present disclosure, the flexible cover window layer includes an organic polymer film and a hard coating layer, and the hard coating layer is disposed on the organic polymer film.

In an embodiment of the present disclosure, a thickness of the organic polymer film has ranges between 30 um and 50 um.

In an embodiment of the present disclosure, the organic polymer film is a colorless transparent polyimide film, and a thickness of the hard coating layer ranges between 10 um and 30 um.

In an embodiment of the present disclosure, the hard coating layer includes a plurality of grooves or a plurality of protrusion structures, and the grooves or the protrusion structures of the hard coating layer contact the glass layer.

Compared with the prior art, in order to solve the above technical problem, in the cover window structure of the embodiment of the present disclosure and the flexible display device, the cover window structure includes the flexible cover window layer and the glass layer. The flexible cover window layer is disposed on the glass layer to effectively improve hardness and bendability of the cover window structure.

### DESCRIPTION OF DRAWINGS

FIG. 1 is a schematic structural diagram of a cover window structure according to an embodiment of the present disclosure.

FIG. 2 is a schematic structural diagram of a cover window structure according to an embodiment of the present disclosure.

FIG. 3 is a schematic structural diagram of a cover window structure according to another embodiment of the present disclosure.

FIG. 4 is a schematic structural diagram of a cover window structure according to another embodiment of the present disclosure.

FIG. 5 is a schematic structural diagram of a cover window structure according to another embodiment of the present disclosure.

FIG. 6 is a schematic structural diagram of a cover window structure according to another embodiment of the present disclosure.

FIG. 7 is a schematic structural diagram of a flexible display device according to an embodiment of the present disclosure.

### DETAILED DESCRIPTION OF PREFERRED EMBODIMENTS

The following description of the various embodiments is provided to illustrate the specific embodiments with reference to the accompanying drawings.

In order to make the above description of the present disclosure and other objects, features, and advantages of the present disclosure more comprehensible, preferred embodiments are described below, and are described in detail below with reference to the accompanying drawings. Furthermore, directional terms described by the present disclosure, such as up, down, top, bottom, front, back, left, right, inner, outer, side, surrounding, center, horizontal, vertical, longitudinal, axial, radial, uppermost or lowermost, etc., are only directions by referring to the accompanying drawings, and thus the used terms are used only for the purpose of describing embodiments of the present disclosure and are not intended to be limiting of the present disclosure.

In the drawings, units with similar structures are labeled with the same reference number.

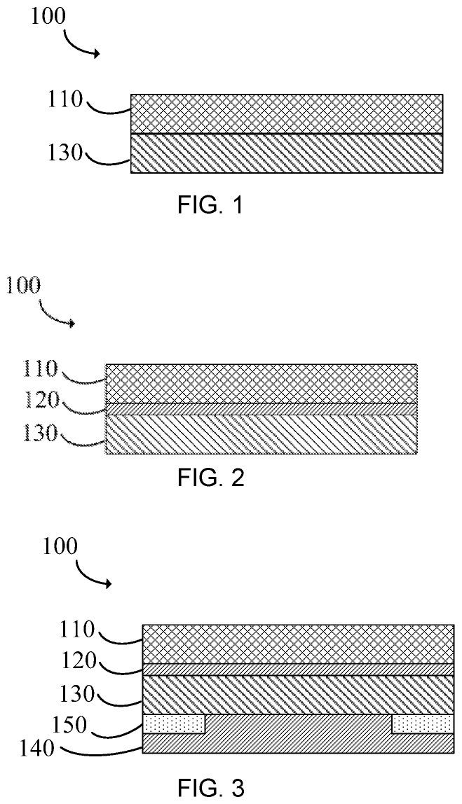

Referring to FIG. 1, a cover window structure 100 of an embodiment of the present disclosure includes a flexible cover window layer 110 and a glass layer 130. The flexible cover window layer 110 is disposed on the glass layer 130. This embodiment effectively improves hardness and bendability of the cover window structure 100 by the flexible cover window layer 110 and the glass layer 130. This ensures flexibility, hardness, and impact resistance of the cover window structure 100.

In details, the cover window structure 100 of the embodiment of the present disclosure combines advantages that the glass layer 130 has high hardness and good impact resistance, and the flexible cover window layer 110 has good bending property and is not easily broken, thereby the cover window structure 100 has bending property, hardness, and impact resistance, and this improves reliability of the cover window structure 100.

Referring to FIG. 2, the cover window structure 100 of an embodiment of the present disclosure further includes a first optical adhesive layer 120. The flexible cover window layer 110, the first optical adhesive layer 120, and the glass layer 130 are sequentially disposed and attached from top to bottom, such that the cover window structure 100 includes a multilayer composite structure.

Because the flexible cover window layer 110 of the embodiment is combined with the glass layer 130, the flexible cover window layer 110 and the glass layer 130 are fixed by the first optical adhesive layer 120 to form a multilayer composite structure, thereby effectively improving hardness and bendability of the cover window structure 100. In addition, the flexible cover window layer 110, the first optical adhesive layer 120, and the glass layer 130 are sequentially disposed and attached from top to bottom, that is, the flexible cover window layer 110 is disposed on an outer side of the cover window structure 100, and the glass layer 130 is disposed on an inside of the window structure 100, this avoids a risk of the glass layer 130 being bent and broken. It is understood that in other embodiments, a composite structure may also be formed by directly coating the flexible cover window layer 110 on the glass layer 130 without a need for the first optical adhesive layer 120, such as the embodiment of FIG. 1.

In details, the flexible cover window layer 110 is a plastic cover window layer. The first optical adhesive layer 120 is an optically clear adhesive layer. A thickness of the first optical adhesive layer 120 is less than or equal to 20 um.

The flexible cover window layer 110 of the embodiment is disposed on an outer side of the cover window structure 100, and therefore, there is no ink step difference to overcome, and a thickness of the first optical adhesive layer 120 can be less than or equal to 20 um, and avoiding an excessive thickness of the first optical adhesive layer 120 results in a hardness of the cover window structure 100 being too low. In addition, a hardness of the glass layer 130 is large, a support performance can be reached, and a hardness of the cover window structure 100 can be effectively improved. The glass layer 130 is disposed on an inner side of the cover window structure 100, and also avoids a risk of potential glass breakage in bending.

Referring to FIG. 3, the cover window structure 100 of an embodiment of the present disclosure further includes a second optical adhesive layer 140 and an ink layer 150. The ink layer 150 is disposed at an end of the glass layer 130 and on one side of the glass layer 130 away from the first optical adhesive layer 120, and the second optical adhesive layer 140 is disposed around the ink layers 150.

In the embodiment of the present disclosure, the flexible cover window layer 110, the first optical adhesive layer 120, the glass layer 130, and the second optical adhesive layer 140 are sequentially disposed and attached from top to bottom, such that a risk of the glass layer 130 being bent and broken and a risk of potential glass breakage in bending can be avoided. In the embodiment of the present disclosure, the second optical adhesive layer 140 has a function that, the flexible cover window structure 110 is directly pasted on the display panel by the second optical adhesive layer 140 when the flexible cover window structure 110 is disposed on the display panel for protecting the display panel.

In details, a thickness of the glass layer 130 is greater than a thickness of the first optical adhesive layer 120, such that an excessive thickness of the first optical adhesive layer 120 can be avoided to cause a hardness of the cover window structure 100 to be too low. In addition, the thickness of the glass layer 130 is greater than the thickness of the first optical adhesive layer 120 and the glass layer 130 has a relatively large hardness, and a supporting performance can be reached, and a hardness of the cover window structure 100 can also be effectively improved.

In details, the glass layer 130 is, for example, an ultra-thin glass layer. The thickness of the glass layer 130 ranges between 30 um and 70 um.

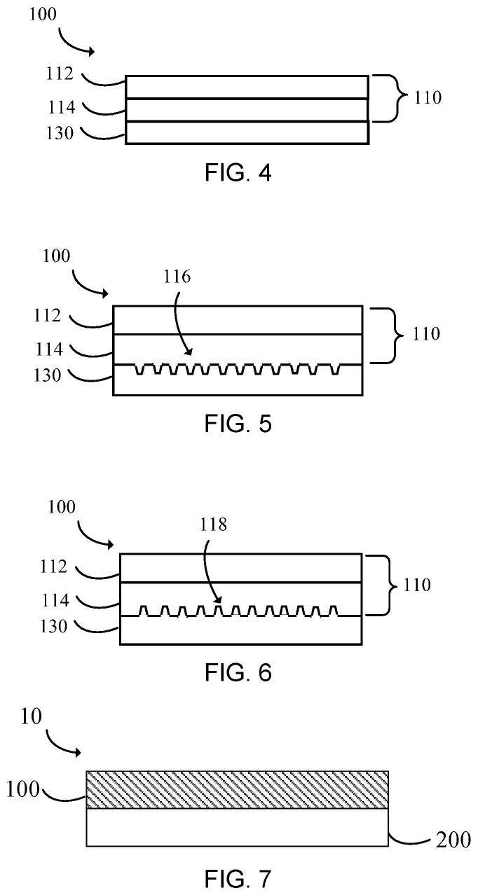

Referring to FIG. 4, the flexible cover window layer 110 of an embodiment of the present disclosure includes an organic polymer film 112 and a hard coating layer 114. The hard coating layer 114 is disposed on the organic polymer film 112 to ensure a bending property, hardness, and impact resistance of the cover window structure 100.

In details, the organic polymer film 112 is prepared by coating on a surface of the glass layer 130. The organic polymer film 112 has a thickness ranging between 30 um and 50 um. The organic polymer film 112 is a colorless transparent polyimide (CPI) film.

In details, the hard coating layer 114 is deposited on a surface of the organic polymer film 112 by coating. A thickness of the hard coating layer 114 ranges between 10 um and 30 um. A material of the hard coating layer 114 includes acrylic acid (Acryl), silane, urethane, or epoxy.

Referring to FIGS. 5-6, in an embodiment of the present disclosure, the hard coating layer 114 includes a plurality of grooves 116 (refer to FIG. 5) or a plurality of protrusion structures 118 (refer to FIG. 6), the grooves 116 or the protrusion structures 118 of the hard coating layer 114 contact the glass layer 130.

In the embodiment, in order to enhance an adhesion between the glass layer 130 and the organic polymer film 112, some grooves 116 or protrusion structures 118 are formed by etching before depositing the organic polymer film 112. This can effectively increase a contact area and bonding force between the organic polymer film 112 and the glass layer 130, and prevent peeling during a bending process.

Referring to FIG. 7, an embodiment of the present disclosure further provides a flexible display device 10 including the above-described cover window structure 100 and a display panel 200. The cover window structure 100 is disposed on the display panel 200. The cover window structure 100 is disposed on a front side (that is, a display side) of the display panel 200 in order to protect the display panel 200.

The flexible display device 10 may be a wearable device such as a smart bracelet, a smart watch, or a virtual reality (VR) device. The flexible display device 10 may be a flexible organic light emitting diode (OLED) display, an electronic book, an electronic newspaper, a mobile phone, a computer, and a television.

Although the present disclosure is described via one or more embodiments, those of ordinary skill in the art can come up with equivalent variations and modifications based upon the understanding of the specification and the accompanying drawings. The present disclosure includes all such modifications and variations, and is only limited by the scope of the appended claims. In particular, as to the various functions performed by the components described above, the terms used to describe the components are intended to correspond to any component performing the specific functions (e.g., which are functionally equivalent) of the components (unless otherwise indicated), even those which are structurally different from the disclosed structure for performing the functions in the exemplary embodiments in the specification shown herein. In addition, although a particular feature in the specification is disclosed in only one of many embodiments, this feature may be combined with one or more features in other embodiments which are desirable and advantageous to a given or particular application. Moreover, the terms “include”, “have”, “consist of”, or variations thereof used in the detailed description or the claims are intended to be used in a manner similar to the term “comprising”.

In summary, although the preferable embodiments of the present disclosure have been disclosed above. It should be noted that those of ordinary skill in the art can make a variety of improvements and substitutions on the premise of not deviating from the technical principle of the present disclosure, and these improvements and substitutions should be encompassed within the protection scope of the present disclosure.

What is claimed is:

1. A cover window structure, comprising:
a glass layer; and
a flexible cover window layer disposed on the glass layer.

2. The cover window structure according to claim 1, further comprising a first optical adhesive layer, wherein the flexible cover window layer, the first optical adhesive layer, and the glass layer are sequentially disposed such that the cover window structure comprises a multilayer composite structure.

3. The cover window structure according to claim 1, wherein the flexible cover window layer is a plastic cover window layer.

4. The cover window structure according to claim 1, wherein the first optical adhesive layer is an optically clear adhesive layer, and a thickness of the first optical adhesive layer is less than or equal to 20 um.

5. The cover window structure according to claim 2, further comprising a second optical adhesive layer and an ink layer, wherein the ink layer is disposed at an end of the glass layer and positioned at one side of the glass layer away from the first optical adhesive layer, and the second optical adhesive layer is disposed around the ink layer.

6. The cover window structure according to claim 1, a thickness of the glass layer ranges between 30 um and 70 um.

7. The cover window structure according to claim 1, wherein the flexible cover window layer comprises an organic polymer film and a hard coating layer, and the hard coating layer is disposed on the organic polymer film.

8. The cover window structure according to claim 7, wherein a thickness of the organic polymer film has ranges between 30 um and 50 um.

9. The cover window structure according to claim 7, wherein the organic polymer film is a colorless transparent polyimide film, and a thickness of the hard coating layer ranges between 10 um and 30 um.

10. The cover window structure according to claim 7, wherein the hard coating layer comprises a plurality of grooves or a plurality of protrusion structures, and the grooves or the protrusion structures of the hard coating layer contact the glass layer.

11. A flexible display device, comprising: a display panel and a cover window structure disposed on the display panel, the cover window structure, comprising:
a glass layer; and
a flexible cover window layer disposed on the glass layer.

12. The flexible display device according to claim 11, wherein the cover window structure further comprises a first optical adhesive layer, the flexible cover window layer, the first optical adhesive layer, and the glass layer are sequentially disposed such that the cover window structure comprises a multilayer composite structure.

13. The flexible display device according to claim 11, wherein the flexible cover window layer is a plastic cover window layer.

14. The flexible display device according to claim 11, wherein the first optical adhesive layer is an optically clear adhesive layer, and a thickness of the first optical adhesive layer is less than or equal to 20 um.

15. The flexible display device according to claim 12, wherein the cover window structure further comprises a second optical adhesive layer and an ink layer, wherein the ink layer is disposed at an end of the glass layer and positioned at one side of the glass layer away from the first optical adhesive layer, and the second optical adhesive layer is disposed around the ink layer.

16. The flexible display device according to claim 11, a thickness of the glass layer ranges between 30 um and 70 um.

17. The flexible display device according to claim 11, wherein the flexible cover window layer comprises an organic polymer film and a hard coating layer, and the hard coating layer is disposed on the organic polymer film.

18. The flexible display device according to claim 17, wherein a thickness of the organic polymer film has ranges between 30 um and 50 um.

19. The flexible display device according to claim 17, wherein the organic polymer film is a colorless transparent polyimide film, and a thickness of the hard coating layer ranges between 10 um and 30 um.

20. The flexible display device according to claim 17, wherein the hard coating layer comprises a plurality of grooves or a plurality of protrusion structures, and the grooves or the protrusion structures of the hard coating layer contact the glass layer.
